(19) United States
(12) Patent Application Publication
(10) Pub. No.: US 2013/0157414 A1
(43) Pub. Date: Jun. 20, 2013

(54) STACKED-DIE PACKAGE AND METHOD THEREFOR

(71) Applicant: NXP B. V., Eindhoven (NL)

(72) Inventors: Chung Hsiung Ho, Kaohsiung City (TW); Wen Hung Huang, Kaohsiung City (TW); Pao Tung Pan, Kaohsiung City (TW); ChihLi Huang, Kaohsiung City (TW); I. Pin Chen, Kaohsiung City (TW); Ching Hui Chang, Kaohsiung City (TW); Wen Jen Kuo, Kaohsiung City (TW); Li Ching Wang, Kaohsiung City (TW)

(73) Assignee: NXP B. V., Eindhoven (NL)

(21) Appl. No.: 13/627,186

(22) Filed: Sep. 26, 2012

Related U.S. Application Data
(60) Provisional application No. 61/577,840, filed on Dec. 20, 2011.

(51) Int. Cl. H01L 21/78

(52) U.S. Cl. 438/113; 257/E21.599

(57) ABSTRACT

Consistent with an example embodiment, there is a semiconductor device comprised of a combination of device die. The semiconductor device comprises a package substrate having groups of pad landings. A first device die is anchored to the package substrate, the first device die having been wire-bonded to a first group of pad landings. At least one subsequent device die is anchored to the first device die. The at least one subsequent device die has an underside profile with recesses defined therein, the recesses of a size are defined to accommodate wires bonded to the first device die; the at least one subsequent device is wire bonded to a second group of pad landings.

### FIELD OF INVENTION

The embodiments of the present disclosure relate to semiconductor device packaging and, more particularly, to packaging semiconductor devices through the stacking multiple die on one another.

### BACKGROUND

The electronics industry continues to rely upon advances in semiconductor technology to realize higher-function devices in more compact areas. For many applications realizing higher-functioning devices requires integrating a large number of electronic devices into a single silicon wafer. As the number of electronic devices per given area of the silicon wafer increases, the manufacturing process becomes more difficult.

Many varieties of semiconductor devices have been manufactured having various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

Each of these semiconductor devices generally includes a semiconductor substrate on which a number of active devices are formed. The particular structure of a given active device can vary between device types. For example, in MOS transistors, an active device generally includes source and drain regions and a gate electrode that modulates current between the source and drain regions.

Furthermore, such devices may be digital or analog devices produced in a number of wafer fabrication processes, for example, CMOS, BiCMOS, Bipolar, etc. The substrates may be silicon, gallium arsenide (GaAs) or other substrate suitable for building microelectronic circuits thereon.

The continuing need to increase the functionality of semiconductor products by packing in more features within ever smaller spaces. In some products a device die may have a set of features realizable in one manufacturing process, while another device die has another set of features only realizable in another separate process; the two sets of features cannot be fabricated in a single process on a single die. Thus, a product requiring those two sets of features necessitates the combining of two product devices to form a combination semiconductor device. For other combination semiconductor devices, the combining of product devices may exceed two and only be limited by the packaging technology.

### SUMMARY

The packaging of semiconductor devices continues to pose a challenge in the reducing of cost and increasing of performance. Furthermore, there is a push to include more functionality in a given packaged product often through combining different devices and putting them together in one package by stacking multiple devices on top of one another. There is a challenge accommodating the bond wires on the stacked devices so that each unit may be properly connected to the overall system in one package.

In an example embodiment, there is a method for assembling semiconductor devices. The method comprises, providing a wafer having a topside and an underside, the topside having a plurality of semiconductor devices, each device having a plurality of bond pads. A die attach film (DAF) is attached to the underside of the wafer. The plurality of semiconductor devices is separated by sawing. A subsequent semiconductor device is formed, wherein a first blade having a first kerf cuts through the DAF and partially through the wafer between each device, at a predetermined depth and wherein a second blade of a second kerf continues through the partial cut completely severing each subsequent semiconductor device from one another, the kerf of the second blade being less than the kerf of the first blade. After sawing, the underside profile of the subsequent semiconductor device has recesses defined therein. Additional features of the example embodiment further include, providing a packaging substrate having a die attach area. A first semiconductor device having a die-attach film on the underside of the first semiconductor device is attached to the die attach area; the first semiconductor device is wire bonded to the die attach area. The subsequent semiconductor device is attached to the topside of the first semiconductor device; the recesses of the subsequent semiconductor device accommodate the loops of a plurality of wire bonds of the first semiconductor device. The subsequent semiconductor device is wire bonded, as well. The first semiconductor device and the subsequent semiconductor device are encapsulated in a molding compound.

In another example embodiment, a semiconductor device is comprised of a combination of device die. The semiconductor device comprises, a package substrate having groups of pad landings. A first device die is anchored to the package substrate, the first device die wire-bonded to a first group of pad landings. At least one subsequent device die is anchored to the first device die, the at least one subsequent device die having an underside profile with recesses defined therein, the recesses of a size defined to accommodate wires bonded to the first device die, the at least one subsequent device wire bonded to a second group of pad landings.

The above summaries of the present disclosure are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1A-1E is a diagram of an example assembly process according to an example embodiment;

FIG. 2 is a side-view of semiconductor assembly having two devices stacked on top of one another, according to an embodiment of the present disclosure;

FIG. 3 is a side-view of a semiconductor assembly having three devices stacked on top of one another, according to an embodiment of the present disclosure; and

FIG. 4A is a flow diagram of an example manufacturing process according to an embodiment of the present disclosure;

FIG. 4B is a flow diagram of the preparation of first semiconductor dies for use in the manufacturing process as depicted in FIG. 4A; and

FIG. 4C is a flow diagram of the preparation of subsequent semiconductor dies for use in the manufacturing process as depicted in FIG. 4A.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The disclosed embodiments have been found useful in the assembly semiconductor devices in which a semiconductor assembly is built with multiple devices stacked upon one another. Upon a first device, a subsequent device is placed thereon. Before placement, the underside of the subsequent device has been sawn to accommodate the electrical connections of the first device. For example, a recess in the subsequent device has recesses provide space for bond wires electrically connecting the first device to the package substrate or lead frame assembly.

The subsequent device is manufactured out of an array of devices; the devices having been fabricated on a wafer substrate. For a given manufacturing process having tooling of a defined size, these arrays may range from fewer than a hundred devices (for large die sizes of complex devices, such as microprocessors) to many thousands (for tiny devices of simpler devices, such as logic gates). The underside of the array is placed on a die attach film (DAF). With a first saw blade of a kerf defined by the particular assembly process, the array of subsequent devices is partially sawn (between device boundaries) through the DAF and underside of the array. With a second saw blade having a narrower kerf, the partial cut is completed, resulting in separated devices. The subsequent device has a recess on the underside. Stacked upon a first device, the recess of the subsequent device accommodates the bond wire loops of the first device.

The semiconductor assembly according to the present invention may be constructed from two or more semiconductor devices. The number devices which may be stacked upon one another would be governed by specific manufacturing requirements.

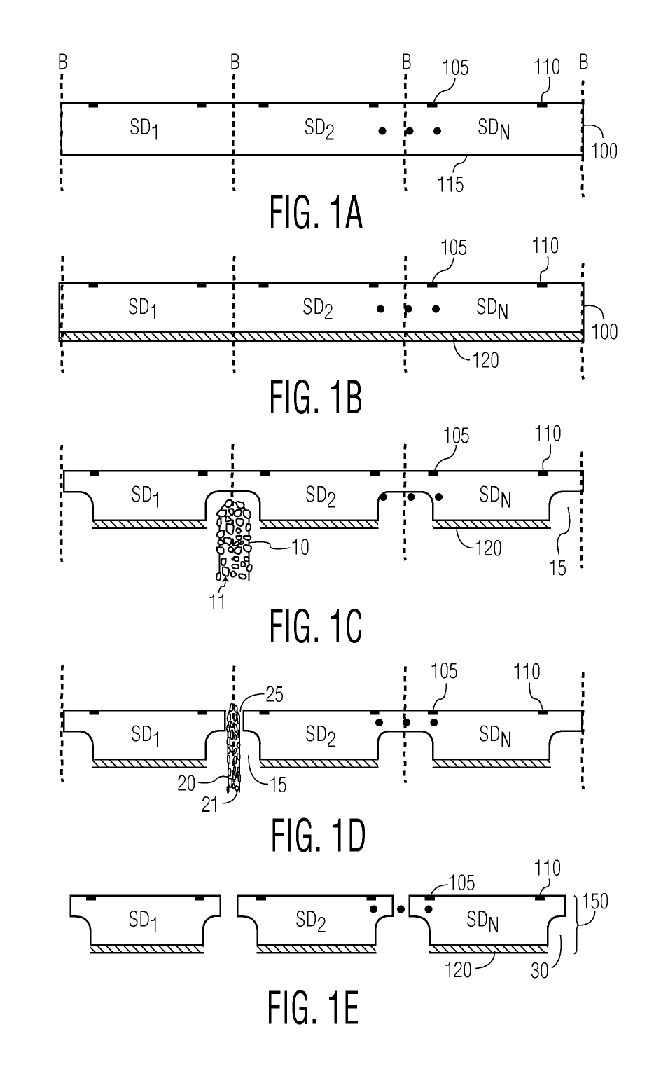

Refer to FIGS. 1A-1E. In an example assembly process to prepare the subsequent semiconductor device (SD) to stack upon a first semiconductor device, according to an embodiment of the present disclosure, a wafer 100 or other substrate of devices (FIG. 1A) is provided. On topside 110, bonding pads 105 define each device (SD₁-SD_{N}); device boundaries defined by dashed lines B. A die attach film (DAF) 120 is applied to the underside 115 of the wafer 100 (FIG. 1B). DAF is an adhesive material that attaches the device die to a die-attach surface. In lieu of a liquid adhesive, DAF may provide superior thickness, wetting, and out-gassing control. Upon die mounting, a heater on the die bonding apparatus heats the substrate and partially cures the DAF. Later in the process, post-stage heating completes the DAF curing.

The process of preparing and separating the subsequent semiconductor device involves a “dual saw” process employing a wide first blade 10 and a narrow second blade 20 to define the subsequent device's profile. In an example process, such saw blades 10 and 20 are coated with diamond aggregate 11 and 21, respectively. The width of a blade's cut is often referred to as the “kerf.” Thus, the wide saw blade 10 would result in a larger kerf than that of the narrow blade 20.

Refer to FIG. 1C. For the wafer 100 of subsequent semiconductor devices, SD₁ through SDₙ The first saw 10 cuts through the DAF 120 and partially through the underside 115 of the wafer 100 at defining a first cut 15 of a sufficient depth as determined by the bonding requirements of the first semiconductor devices. These bonding requirements may include, but are not limited to, the loop height of the bond, the size of the tooling having to negotiate the recess, whether the first semiconductor device is wire bonded prior to placement of the subsequent semiconductor devices, etc. The first cut 15 is continued with a second saw 20 until the semiconductor devices SD₁ through SDₙ are separated, as evidenced by the second cut 25. See FIG. 1D.

Refer to FIG. 1E. Through known production techniques, the subsequent devices SD₁, SD₂ through SD_{N} are separated out and put on partitioned plates that resemble waffles in appearance (i.e., the process often referred to as “plating.”). The edge profile 150 shows a recess 30 that will accommodate the tooling and bonding for the first semiconductor device. These “plated” devices will be attached to the first semiconductor device in the packaging process.

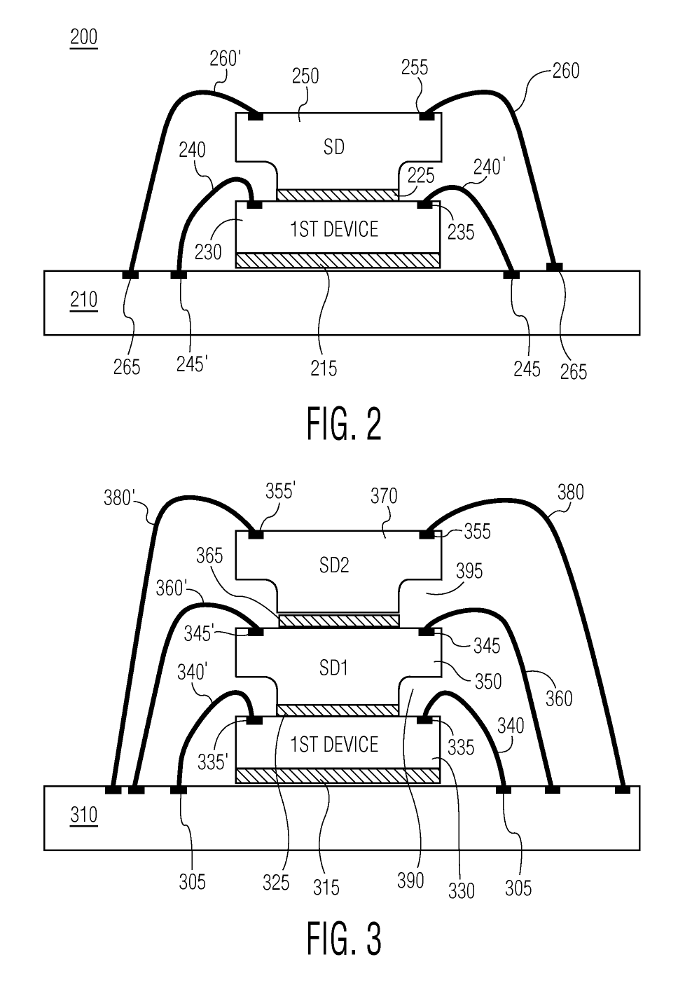

Having obtained the SD devices, one or more of these devices may be attached to the first semiconductor device. The two devices are then wire bonded to a package substrate or lead frame, combining the functionality of the two devices into one combination integrated circuit device. Refer to FIG. 2. A combination integrated circuit device 200 has a substrate 210. Upon the substrate 210, a first semiconductor device 230 is anchored to the substrate 210 with a die attach film (DAF) 215. Upon the first semiconductor device 230, a subsequent semiconductor device 250 is anchored to the first semiconductor device 230 with a DAF 225, as well. Each device's respective bond pads 235 and 255 are coupled via bond wires 240 and 260 to pad landings 245 and 265 on the substrate. After wire bonding, the device may be sealed in a suitable encapsulating material.

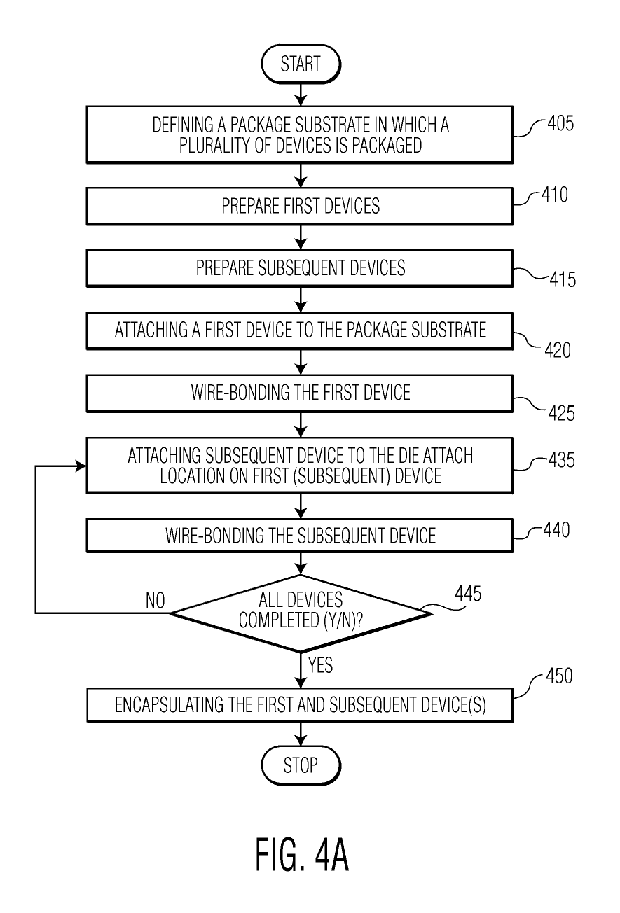

In another example embodiment, the SD device may have three devices stacked upon one another. Refer to FIG. 3. On a package substrate or lead frame 310, a first device 330 is attached to the substrate 310 with a DAF 315. Upon bond pads 335, wire bonds 340 connect the first semiconductor device 330 to pad landings 305 on the substrate 310. These pad landings 305 in turn connect the package substrate 310 to the outside world through conductive paths within the substrate 310 to external contacts (not illustrated). Upon the first semiconductor device 330, a first subsequent device 350 whose underside has been sawn according to an embodiment of the present disclosure, is attached with a DAF 325. The subsequent device 350 has a recess sufficient to accommodate the loop of bond wire 340 of the first device 330. Bond wires 360 are attached to bond pads 345 and are connected to pad landings 305 on the substrate 310. An additional subsequent device 370 is attached with DAF 365 to the first subsequent device 350. As with the first subsequent device 350, bond wires 380 are attached to bond pads 355 and connect the additional subsequent device 370 to the package substrate 310 at pad landings 305. The additional subsequent device 370 has recesses 395 to accommodate the loops of bond wires 360 of the first subsequent device 350.

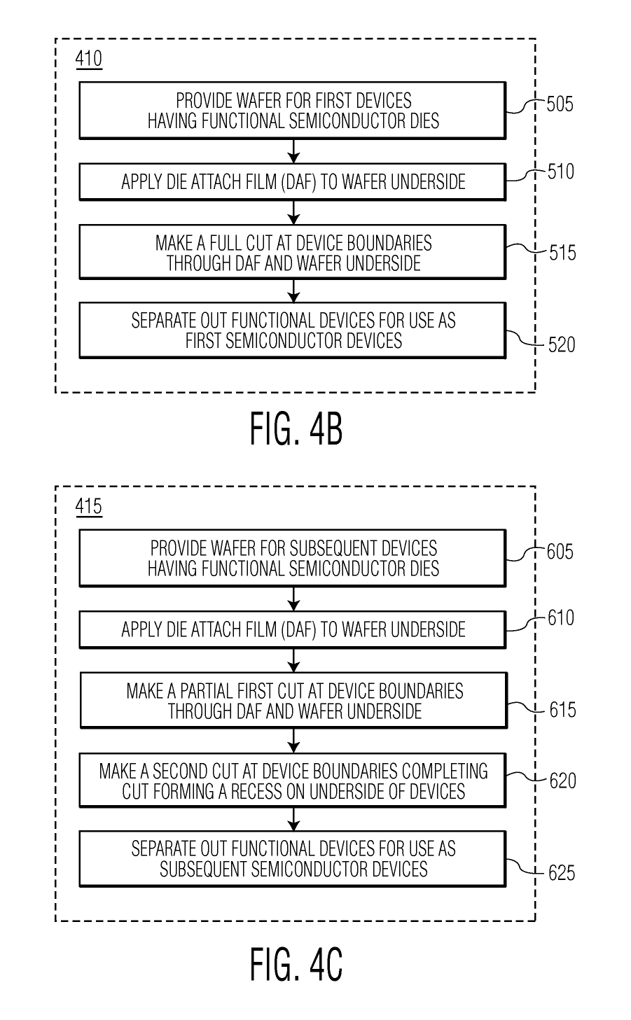

In another example embodiment, a process for manufacturing devices is illustrated in FIGS. 4A-4C. The user first defines a package substrate in which a plurality of devices is packaged 405. First semiconductor devices are prepared 410. Refer to FIG. 4B. Wafers for first devices having functional semiconductor dies are provided 505. Die attach film (DAF) is applied to the wafer underside 510. A full cut at device boundaries through the DAF and underside is made 515. Functional dies for use as first semiconductor devices are separated out 520. Subsequent semiconductor devices are prepared 415. Refer to FIG. 4C. In an example process, a wafer having functional semiconductor dies is provided 605. DAF is applied to the wafer underside 610. A partial first-cut is made at device boundaries through the DAF and wafer underside 615. A second cut at device boundaries is made, forming a recess on underside of devices 620. Note that the first cut is accomplished with a saw blade having a kerf greater than that of the second cut, forming a recess on the underside of the device. Functional die for use as subsequent semiconductor devices are separated out 625. In an example process, the wafer thickness is in the range of about 600 to 800 μm, after backside grind the thickness may be in the range of about 100 to 400 μm. The thickness of the wafer substrate provides the spacing during subsequent sawing.

In either case for first semiconductor devices or subsequent semiconductor devices, these separated out devices may be plated out in waffle packs for later use in the assembly process.

Having prepared the semiconductor devices with the processes depicted in FIGS. 4B and 4C, the first device is attached to the package substrate 420. The DAF on the underside of the first device anchors the first device to a die attach region on the package substrate. The first device is wire-bonded 425. A subsequent device 435 is attached to a defined area on the first device. As with the first device, DAF on the underside of the subsequent device anchors it to the defined area on the first device. The subsequent device is wire-bonded 440. The specific process will govern the degree of curing the DAF undergoes in between the die attachment of the first and subsequent dies. The previously attached die should have sufficient anchor strength to withstand rigors of subsequent die attach and wire bonding processes. The number of devices to build the combination semiconductor device will have been defined early in the process. If all the devices have been assembled on the substrate 445, the first and subsequent semiconductor devices are then encapsulated 450.

Although DAF may be suitable for a given process, in another example process, device die may be attached with a liquid adhesive provided that the process has sufficient control to maintain a consistent adhesive thickness, viscosity, hardness, etc. After adhesive curing, the two-cut sawing process may still be realized.

In an example process, the ball height and bond wire loop height determines how deep a recess is required; if more die-to-die spacing height is needed, the back grinding of the wafer substrate would be less. In some example modern processes, a recess of about 50 μm is sufficient. In other example processes, a recess greater than 50 μm to about 150 μm would be appropriate. The recess in the subsequent semiconductor device accommodates the wire bond loops of the previous or first semiconductor device; ultimately, the particular assembly process governs the suitable recess dimensions.

The techniques outlined in the present disclosure may be used in a variety of package types, for example, ball grid array (BGA), low-profile fine-pitch ball grid array (LFBGA), and thin and fine-pitch ball grid array (TFBGA), etc. but is not limited to any particular package type. For ceramic devices, the cavity depth of the package determines whether the lid can accommodate the multiple-bonded devices. Encapsulating the ceramic device for a particular package would merely entail placing a lid on the package cavity and sealing it (usually a solder seal).

If the subsequent device is smaller than the first semiconductor device, known die attach methods may be used. However, for a subsequent device of almost equal or even larger than the first semiconductor device, there must be sufficient space to accommodate the bond wire loops of the first semiconductor device underneath the subsequent device, the in a manner according to an embodiment according to the present disclosure, the dual sawing of the subsequent device creates the necessary space.

Numerous other embodiments of the invention will be apparent to persons skilled in the art without departing from the spirit and scope of the invention as defined in the appended claims.

1. A method for assembling semiconductor devices, the method comprising:
providing a wafer having a topside and an underside, the topside having a plurality of semiconductor devices, each device having a plurality of bond pads;
attaching a die attach film (DAF) the underside of the wafer;
separating the plurality of semiconductor devices by sawing, and forming a subsequent semiconductor device,
wherein a first blade having a first kerf cuts through the DAF and partially through the wafer between each device, at a predetermined depth;
wherein a second blade of a second kerf continues through the partial cut completely severing each subsequent semiconductor device from one another, the kerf of the second blade being less than the kerf of the first blade;
whereby the underside profile of the subsequent semiconductor device has recesses defined therein.

2. The method as recited in claim 1, further comprising,
providing a packaging substrate having a die-attach area;
attaching a first semiconductor device having a die-attach film on the underside of the first semiconductor device;
wire bonding the first semiconductor device to the packaging substrate;
attaching the subsequent semiconductor device to the topside of the first semiconductor device, the recesses of the subsequent semiconductor device accommodating the loops of a plurality of wire bonds of the first semiconductor device;
wire bonding the subsequent semiconductor device; and
encapsulating the first semiconductor device and the subsequent semiconductor device in a molding compound.

3. The method as recited in claim 1, wherein in lieu of a DAF, a liquid adhesive is applied to the underside of the wafer, partially cured so as to become solid, resulting in a film of a thickness.

4. A semiconductor device comprised of a combination of device die, the semiconductor device comprising:
a package substrate having groups of pad landings;
a first device die anchored to the package substrate, the first device die wire-bonded to a first group of pad landings; and
at least one subsequent device die anchored to the first device die, the at least one subsequent device die having an underside profile with recesses defined therein, the recesses of a size defined to accommodate wires bonded to the first device die, the at least one subsequent device wire bonded to a second group of pad landings.

5. The semiconductor device as recited in claim 4, wherein the first device die and at least one subsequent device die are anchored with one of the following selected from the group of: eutectic die attach, liquid adhesive, die attach film (DAF).

6. The semiconductor device as recited in claim 5, wherein the combination of device die is encapsulated.

7. A method for assembling combination semiconductor devices, the method comprising:
defining a package substrate for assembling the combination of semiconductor devices;
providing a wafer having functional devices;
applying a die attach film (DAF) to the wafer underside;
making a partial first cut with a blade of a first kerf at device boundaries through the DAF and the wafer underside;
making a second cut at device boundaries with a blade of a second kerf, the second kerf wider than the first kerf, the second cut forming recesses on the underside of devices;
separating out functional devices for use as subsequent devices;
attaching a first device to the package substrate;
wire-bonding the first device;
attaching the subsequent device to a defined area on the first device;
wire-bonding the subsequent device;
determining whether all devices have been combined,
if no, attaching another subsequent device to a defined area on the subsequent device;
if yes, encapsulating the first and subsequent devices.
